(19) United States
(12) Patent Application Publication
(10) Pub. No.: US 2021/0371975 A1
(43) Pub. Date: Dec. 2, 2021

(54) METHOD OF PRODUCING SILICATE FLUORESCENT MATERIAL, SILICATE FLUORESCENT MATERIAL, AND LIGHT EMITTING DEVICE

(71) Applicant: NICHIA CORPORATION, Anan-shi (JP)

(72) Inventors: Ryuta MIYAI, Komatsushima-shi (JP); Kazuya NISHIMATA, Anan-shi (JP); Shoji HOSOKAWA, Tokushima-shi (JP)

(73) Assignee: NICHIA CORPORATION, Anan-shi (JP)

(21) Appl. No.: 17/303,476

(22) Filed: May 28, 2021

(30) Foreign Application Priority Data
May 29, 2020 (JP) 2020-094897

(51) Int. Cl. C23C 16/442; C23C 16/40; C09K 11/02; C09K 11/08; C23C 16/56

(52) U.S. Cl. CPC C23C 16/442; C23C 16/403; C23C 16/56; C09K 11/0838; C09K 11/025

(57) ABSTRACT

A method of producing a silicate fluorescent material, the method includes: providing a raw material mixture that contains an M source containing M, an Mg source, an Eu source, and an Si source, and optionally an Mn source, obtaining at least one core particle comprising a silicate fluorescent composition having a formula: (M_{1-c}Eu_{c})₃ₐ(Mg_{1-d}Mn_{d})_{b}Si₂O₈, in which M is at least one element selected from the group consisting of Ca, Sr, and Ba, and a, b, c, and d are numbers respectively satisfying 0.93≤a≤1.07, 0.90≤b≤1.10, 0.016≤c≤0.090, and 0≤d≤0.22; using a chemical vapor deposition method, depositing aluminum oxide on surfaces of the at least one core particle; and heat treating at a temperature in a range of 210° C. to 490° C. in an oxygen-containing atmosphere.

### CROSS-REFERENCE TO RELATED PATENT APPLICATION

The present application claims priority under 35 U. S. C. § 119 to Japanese Patent Application No. 2020-094897, filed May 29, 2020. The contents of Japanese Patent Application No 2020-094897 are incorporated herein by reference in their entirety.

### BACKGROUND

### Technical Field

The present disclosure relates to a method of producing a silicate fluorescent material, to the silicate fluorescent material, and to a light emitting device.

### Description of Related Art

There have been light emitting devices in which light emitting diodes (LEDs) or laser diodes (LDs) are combined with fluorescent materials that respectively configured to emit light of blue, green, yellow, red, and deep red colors.

Examples of fluorescent materials to emit blue light include a fluorescent material having a silicate composition expressed as Sr₃MgSi₂O₈ activated with europium (hereinafter may also be referred to as a “silicate phosphor or fluorescent material”).

For example, Japanese translation of PCT international application No. 2017-502157 shows silicate phosphors deposited with aluminum oxide by an atomic layer deposition (ALD) process.

### SUMMARY OF THE INVENTION

Silicate fluorescent material are required to further improve durability. Accordingly, it is an object of certain embodiments of the present disclosure to provide a method of producing a silicate fluorescent material that has improved durability, the silicate fluorescent material, and a light emitting device.

The present disclosure includes embodiments as described below. A method of producing a silicate fluorescent material according to a first aspect of the present disclosure, the method including, providing a raw material mixture that contains an M source containing M that is at least one element selected from the group consisting of Ca, Sr, and Ba, an Mg source, an Eu source, and an Si source, and optionally an Mn source, obtaining core particles comprising a silicate fluorescent composition represented by a formula (M_{1-c}Eu_{c})₃ₐ(Mg_{1-d}Mn_{d})_{b}Si₂O₈ in which M is the at least one element selected from the group consisting of Ca, Sr, and Ba, and a, b, c, and d are numbers respectively satisfying 0.93≤a≤1.07, 0.90≤b≤1.10, 0.016≤c≤0.090, and 0.0≤d≤0.22); using a chemical vapor deposition method, depositing aluminum oxide on surfaces of the core particles; and heat treating in an oxygen-containing atmosphere at a temperature in a range of 210° C. to 490° C.

A method of producing a silicate fluorescent material according to a second aspect of the present disclosure, the method including, providing a raw material mixture that contains an M source containing M that is at least one element selected from the group consisting of Ca, Sr, and Ba, an Mg source, an Eu source, and an Si source, and optionally an Mn source, obtaining core particles comprising the silicate fluorescent composition of the formula indicated above: heat treating in an oxygen-containing atmosphere at a temperature in a range of 210° C. to 490° C.; and using a chemical vapor deposition method, depositing aluminum oxide on surfaces of the core particles.

A silicate fluorescent material according to a third aspect of the present disclosure, the silicate fluorescent material includes at least one core particle comprising a silicate fluorescent composition and a film containing aluminum oxide on a surface of the core particle, the silicate fluorescent composition including M that is at least one element selected from the group consisting of Ca, Sr, and Ba, and Mg, Eu, and Si, and optionally Mn. In the silicate fluorescent composition, when a molar ratio of Si in the composition is 2, a total molar ratio of M and Mn in the composition is a product of 3 and a variable a, a molar ratio of Eu in the composition is a product of 3, the variable a and a variable c, and a molar ratio of Mn in the composition is a product of a variable b and a variable d, in which the variable a is in a range of 0.93 to 1.07; the variable b is in a range of 0.90 to 1.10; the variable c is in a range of 0.016 to 0.090; and the variable d is in a range of 0 to 0.22; and an amount of aluminum in the film containing aluminum oxide is in a range of 0.86 to 0.98 mass % relative to a total mass amount of the silicate fluorescent material.

A light emitting device according to a fourth aspect to the present disclosure, the light emitting device includes the silicate fluorescent material and an excitation light source.

According to certain embodiments of the present disclosure, a method of producing a silicate fluorescent material having good durability, a silicate fluorescent material, and a light emitting device can be provided.

### BRIEF DESCRIPTION OF THE DRAWINGS

FIG. 1 is a flowchart illustrating a method of producing a silicate fluorescent material according to an embodiment of the present disclosure.

FIG. 2 is a flowchart illustrating a method of producing a silicate fluorescent material according to an embodiment of the present disclosure.

FIG. 3 is a flowchart illustrating a method of producing a silicate fluorescent material according to an embodiment of the present disclosure.

FIG. 4 is a schematic cross-sectional view of a light emitting device according to an embodiment of the present disclosure.

FIG. 5 is a SEM secondary electron image of a silicate fluorescent material according to Example 2.

FIG. 6 is a SEM secondary electron image of a silicate fluorescent material according to Comparative Example 1.

FIG. 7 is a SEM secondary electron image of a silicate fluorescent material according to Comparative Example 5.

### DETAILED DESCRIPTION

A method of producing a silicate fluorescent material, a silicate fluorescent material, and a light emitting device according to certain embodiments will be described below. The embodiments shown below are intended as illustrative to give a concrete form to technical ideas of the present invention, and the scope of the invention is not limited to the methods of producing silicate fluorescent materials, silicate fluorescent materials, and light emitting devices described below. In the present specification, the relation between the color names and the chromaticity coordinates, the relation between the range of wavelength of light and the color name of single color light, and the like conform to JIS Z8110.

### Method of Producing Silicate Fluorescent Material

The method of producing a silicate fluorescent material, the method includes: providing a raw material mixture that contains an M source containing at least one element M selected from a group consisting of Ca, Sr, and Ba, an Mg source, an Eu source, and an Si source, and optionally an Mn source, obtaining score particles comprising a silicate fluorescent composition represented by a formula:

(M_{1-c}-Eu_{c})₃ₐ(Mg_{1-d}Mn_{d})_{b}Si₂O₈

in which M is at least one element selected from the group consisting of Ca, Sr, and Ba, and a, b, c, and d are numbers respectively satisfying 0.93≤a≤1.07, 0.90≤b≤1.10, 0.016≤c≤0.090, and 0≤d≤0.22; using a chemical vapor deposition technique (hereinafter may be referred to as “CVD technique”), depositing aluminum oxide on surfaces of the core particles; and heat treating at a temperature in an oxygen-containing atmosphere in a range of 210° C. to 490° C.

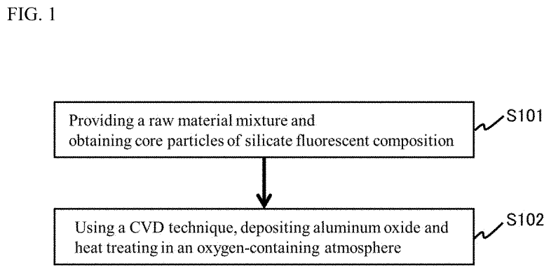

FIG. 1 to FIG. 3 are each a flowchart illustrating an example of a sequence of steps of a method of producing a silicate fluorescent material. Referring to the drawings, steps of methods of producing silicate fluorescent materials will be described below with reference to respective drawings. As shown in FIG. 1, a method of producing a silicate fluorescent material includes providing a raw material mixture and obtaining core particles comprising the silicate fluorescent composition of the formula indicated above: S101, using a CVD technique, depositing aluminum oxide on surfaces of the core particles, and heat treating in an oxygen-containing atmosphere at a temperature in a range of 210 to 490° C.

As shown in FIG. 1, a method of producing a silicate fluorescent material may include heat treating in an oxygen-containing atmosphere at a temperature in a range of 210 to 490° C. while depositing aluminum oxide using a CVD technique on the s core particles. In the method of producing a silicate fluorescent material, the depositing aluminum oxide using a CVD technique on the surfaces of the core particles and the heat treating in an oxygen-containing atmosphere at a temperature in a range of 210° C. to 490° C. may be included as a single step S102.

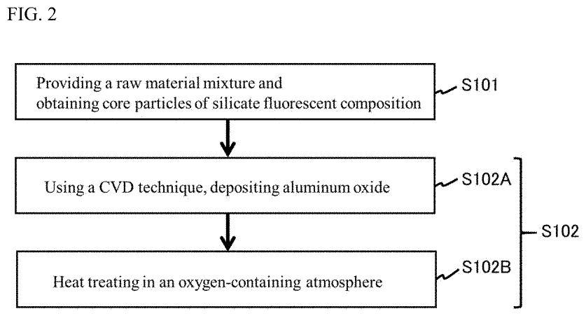

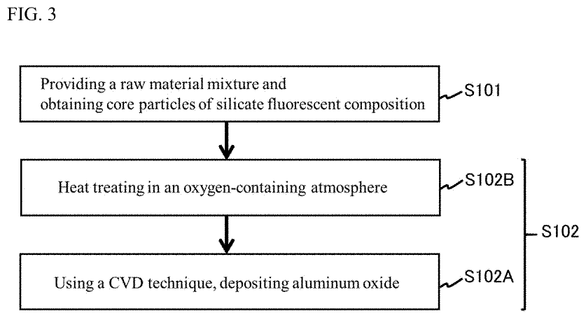

Alternatively, as shown in FIG. 2 and FIG. 3, two steps, a step S102A of using a CVD technique, depositing aluminum oxide on surfaces of the core particles, and a step S102B of heat treating in an oxygen-containing atmosphere at a temperature in a range of 210 to 490° C. may be performed. The sequence of step S102A of using a CVD technique, depositing aluminum oxide and the step S102B of heat treating in an oxygen-containing atmosphere at a temperature in a range of 210 to 490° C., may be such that as shown in FIG. 2, the step S102B of heat treating may be performed after the step S102A of depositing aluminum oxide. As shown in FIG. 2, the method of producing a silicate fluorescent material may include using a CVD technique, depositing aluminum oxide on surfaces of the core particles, and heat treating in an oxygen-containing atmosphere at a temperature in a range of 210 to 490° C., which may be performed in this order. As shown in FIG. 3, the step of heat treating S102B may be performed prior to the step S102A of depositing aluminum oxide. As shown in FIG. 3, the method of producing a silicate fluorescent material may include heat treating in an oxygen-containing atmosphere at a temperature in a range of 210 to 490° C., and using a CVD technique, depositing aluminum oxide on surfaces of the score particles, which may be performed in this order.

### Obtaining Core Particles of Silicate Fluorescent Composition

In the step of obtaining core particles comprising the silicate fluorescent composition of the formula indicated above, raw materials of an M source containing at least one element M selected from a group consisting of Ca, Sr, and Ba, an Mg source, an Eu source, and an Si source, and optionally an Mn source are provided. For each of the M source, the Mg source, the Si source, and optionally the Mn source, a metal made of one or more corresponding elements or a compound containing one or more corresponding elements can be used. For a compound containing element M, a compound containing Mg, a compound containing Eu, and optionally a compound containing Mn, at least one compound selected from a group consisting of halogens, oxides, carbonates, phosphates, silicates and ammonium salts containing respective elements can be used. For the compound containing Si, an oxide, a hydroxide, an oxynitride, a nitride, an imide compound, or an amide compound can be used. Specific examples of the M sources include SrF₂, SrCl₂, SrCO₃, CaF₂, CaCl₂), CaCO₃, BaF₂, BaCl₂, and BaCO₃. Specific examples of the Mg sources include MgF₂, MgCl₂, MgO, and MgCO₃. Specific examples of the Eu sources include metal europium, Eu₂O₃, EuN, and an imide compound containing Eu, and an amide compounds containing Eu. Specific examples of the Si sources include metal silica, SiO₂, Si₃N₄, and Si(NH₂)₂. Specific examples of the optional Mn sources include MnF₂, MnCl₂ and MnCO₃. It is preferable that the M source, the Mg source, the Eu source, the Si source and the optional Mn source are weighed and included in the raw material mixture as described below. The M source, the Mg source, the Eu source, the Si source and the optional Mn source may be referred to as each element source.

A raw material mixture that contain the M source, the Eu source, the Mg source, the Si source and optionally the Mn source is provided, with a raw material ratio of each element source that can obtain the composition represented by the formula shown below.

(M_{1-c}-Eu_{c})₃ₐ(Mg_{1-d}Mn_{d})_{b}Si₂O₈

(In the formula, M is at least one element selected from the group consisting of Ca, Sr, and Ba, and a, b, c, and d respectively satisfy 0.93≤a≤1.07, 0.90≤b≤1.10, 0.016≤c≤0.090, 0≤d≤0.22).

In the composition represented by the formula shown above, a molar ratio of Eu in the composition expressed by a product of the variable a, which is in a range of 0.93 to 1.07, the variable c, and 3. The variable c is preferably in a range of 0.016 to 0.090 (0.016≤c≤0.090), may be in a range of 0.022 to 0.082 (0.022≤c≤0.082), may be in a range of 0.025 to 0.079 (0.025≤c≤0.079), or may be in a range of 0.031 to 0.072 (0.031≤c≤0.072).

Mn may not be included in the composition expressed in the above formula. In the composition combined by the above formula, the mole ratio of Mn is expressed as the product of the variable b, which is in a range of 0.90 to 1.10, and the variable d, and the variable d can be in a range of 0.009 to 0.11 (0.009≤d≤0.11).

The M source is weighed and included in the raw material mixture such that in the 1-mole composition of the core particles of the silicate fluorescent composition of the formula indicated above, when a molar ratio of Si in the composition is 2, a molar ratio of the element M in the composition is preferably in a range of 2.75 to 2.95, more preferably in a range of 2.77 to 2.93, further preferably in a range of 2.78 to 2.92, still further preferably in a range of 2.80 to 2.90.

The Eu source is weighed and included in the raw material mixture such that in the 1-mole composition of the core particles of the silicate fluorescent composition of the formula indicated above, when a molar ratio of Si in the composition is 2, a molar ratio of Eu in the composition is preferably in a range of 0.05 to 0.25, more preferably in a range of 0.07 to 0.23, further preferably in a range of 0.08 to 0.22, still further preferably in a range of 0.10 to 0.20.

The M source and the Eu source are weighed and included in the raw material mixture such that in the 1-mole composition of the core particles of the silicate fluorescent composition of the formula indicated above, when a molar ratio of Si in the composition is 2, the total molar ratio of elements M and Eu in the composition is preferably in a range of 2.8 to 3.2, more preferably in a range of 2.9 to 3.1.

The Mg source is weighed and included in the raw mixture such that in the 1-mole composition of the core particles of the silicate fluorescent composition of the formula indicated above, when a molar ratio of Si in the composition is 2, the molar ratio of Mg contained in the composition is preferably in a range of 0.9 to 1.1, more preferably in a range of 0.95 to 1.05.

The Mn source does not have to be contained in the raw material mixture. The M source may be weighed and included in the raw material mixture such that in the 1-mole composition of the core particles of the silicate fluorescent composition of the formula indicated above, the mole ratio of Mn may be in a range of 0 to 0.20, or in a range of 0.01 to 0.10.

### Raw Material Mixture

The element sources are weighed and wet-mixed or dry-mixed by using a mixing machine to obtain a raw material mixture. For the mixing machine, a pulverizing machine generally used in the industry, such as a ball mill, a vibration mill, a roll mill, or a jet mill can be used. The specific surface area of a raw material can be increased by pulverizing. In order to obtain a certain range of specific surface area of the particles of the element sources, which are the raw materials, classification may be performed. For the classification of the particles of the element sources, a wet separating device such as a settling tank, a hydro-cyclone, or a centrifugal separating device, or a dry separating device such as a cyclone separating device, an air separating device, or the like, commonly used in the industry may be used.

### Flux

The raw material mixture may include a flux. When a flux is included in the raw material mixture, the reaction of the element sources is accelerated while calcinating the raw material mixture that will be described below, allowing solid-state reaction to proceed uniformly, resulting in larger particle size, which allows obtaining the core particles of the silicate fluorescent composition with good luminescence properties. For the flux, a halide can be used. When a halide is used as flux, liquid phase transition of the halide occurs at a temperature almost equal to the temperature at which the raw material mixture is calcinated, which allows more uniform progression of the solid phase reaction among the element sources, resulting in the core particles of the silicate fluorescent composition with large particle sizes and good luminescence properties. Examples of halide used as flux include a chloride or a fluoride, which contains one or more rare earth metal elements such as cerium or europium, and a chloride or a fluoride, which contains one or more alkaline metal elements or alkaline earth metal elements. When an element contained in the flux is also a constituent element in the composition of the core particles of the silicate fluorescent composition, the molar ratio of the element contained in the flux may be adjusted such that the core particles of the silicate fluorescent composition to be produced have a predetermined composition, and the flux may be added to the raw material mixture as a part of the element source. Though alternatively, the flux may be further added to the raw material mixture as a part of the element source, regardless of the composition of the core particles of the silicate fluorescent composition that to be produced. When the raw material mixture contains a flux, in order to further facilitate the reaction of each element source, the addition amount of the flux is preferably 10 parts by mass or less, may be 5 parts by mass or less, or may be 1 part by mass or greater, with respect to 100 parts by mass of the raw material mixture that does not contain the flux.

### Calcining

The raw material mixture can be calcined to obtain the core particles of the silicate fluorescent composition of the formula indicated above. The raw material mixture can be placed on a crucible or a boat made of materials such as silicon carbide (SiC), quartz, alumina, boron nitride (BN), and calcined in a furnace.

The calcining temperature of the raw material mixture is preferably in a range of 1,100 to 1,500° C., more preferably in a range of 1,300 to 1,450° C. When the calcining temperature is in a range of 1,100 to 1,500° C., the core particles of the silicate fluorescent composition of the formula indicated above having a predetermined composition can be obtained. In the calcining, a primary calcining followed by a secondary calcining may be performed, or multiple times of calcining may be performed. The duration of a single calcining is preferably in a range of 1 to 30 hours. A multistage calcining with stepwise change in calcinating temperature may also be performed. For example, a first-stage calcining may be performed at a temperature in a range of 800 to 1,000° C., then the temperature is gradually increased, a second-stage calcining may be performed at a temperature in a range of 1,100 to 1,500° C.

The calcining of the raw material mixture is preferably performed in a reducing atmosphere. Such a reducing atmosphere may be a nitrogen atmosphere containing hydrogen gas that has reducing property. The content of nitrogen gas in the nitrogen atmosphere that includes the reducing hydrogen gas is preferably 70 volume % or greater, more preferably 80 volume % or greater, further preferably 90 volume % or greater. The content of hydrogen gas in the nitrogen atmosphere that includes the reducing hydrogen gas is preferably 1 volume % or greater, more preferably 5 volume % or greater, further preferably 10 volume % or greater. The calcining of the raw material mixture may be performed in a reducing atmosphere that is created using solid carbon in air atmosphere. Calcining the raw material mixture in a strong reducing atmosphere allows for obtaining core particles of the silicate fluorescent composition of the formula indicated above with good luminescence properties. For example, when a raw material mixture is calcined in a strong reducing atmosphere, the resulting calcined product has an increased content of bivalent Eu. Although bivalent Eu can be easily oxidized to trivalent Eu, when the raw material mixture is calcined in a strong reducing atmosphere, the trivalent Eu (Eu³⁺) contained in the raw material mixture can be reduced into divalent Eu (Eu²⁺). This results in the calcined product with an increased content of the bivalent Eu (Eu²⁺), which serves as luminous center, and core particles of the silicate fluorescent composition of the formula indicated above having good luminescence properties.

The calcining may be performed in a normal atmosphere (about 0.1 MPa) or in a pressurized atmosphere at a gauge pressure in a range of 0.1 to 200 MPa. The higher the heat treatment temperature, the easier the crystalline structure is to break down, but by creating a pressurized atmosphere, the degradation of the crystalline structure can be reduced, such that a decrease in the luminescent intensity of the resulting core particles of the silicate fluorescent composition of the formula indicated above can be reduced. The pressure of the heat treatment atmosphere is more preferably in a range of 0.1 to 100 MPa, further preferably in a range of 0.5 to 10 MPa, and in terms of ease of producing, further more preferably 1.0 MPa or less, in terms of gauge pressure.

Post-Processing after Calcining

The raw material mixture may be calcined, a post-processing may be performed on obtained calcined product, to obtain silicate fluorescent material fluorescent material. As such a post-processing, or example, crushing, dispersion, solid-liquid separation, drying, etc. may be carried out. Solid-liquid separation can be carried out by using a technique commonly used in the industry, such as filtering, vacuum filtering, pressure filtering, centrifugating, or decantating. Drying can be carried out by using a device commonly used in the industry, such as a vacuum drying machine, a hot-air heating drying machine, a conical drying machine, or a rotary evaporation machine. A post-processing may be performed as needed on the calcined product, which is then processed into the core particles of the silicate fluorescent composition of the formula indicated above.

The resulting core particles of the silicate fluorescent composition are formed to have a median particle diameter in a range of 1 to 40 μm, may be in a range of 3 to 35 μm, may be in a range of 5 to 35 μm, or may be in a range of 10 to 30 μm. When the median particle diameter of the core particles of the silicate fluorescent composition is in a range of 1 to 40 μm, aluminum oxide can be applied to the entire surfaces of the core particles of the silicate fluorescent composition in the step of depositing aluminum oxide described below. The median particle diameter of the core particles of the silicate fluorescent composition is represented by a volume-cumulative (50%) average particle size (median diameter: Dm), a size of particle taken at 50% of the volume-cumulative frequency from the smaller diameter side, measured by using a laser diffraction-type particle-size distribution measuring method. Laser diffraction-type particle-size distribution measuring method is a method of measuring particle size without distinguishing primary and secondary particles, by using scattered light of the laser light irradiated on the particles. The laser diffraction-type particle-size distribution measuring method can be performed using a commercially available instrument, such as a laser diffraction-type particle-size distribution measuring instrument (e.g. MALVERN, MASTER SIZER3000).

### Depositing Aluminum Oxide and Heat Treating

Depositing aluminum oxide to the surfaces of the obtained core particles of the silicate fluorescent composition of the formula indicated above, using a CVD technique. In the step of depositing aluminum oxide and heat treating, it is preferable to attach aluminum oxide to the surfaces of core particles of the silicate fluorescent composition using a fluidized bed CVD technique. The fluidized bed CVD technique can be performed using a commercially available fluidized bed CVD reactor for particle coating.

An Aluminum compound can be used as the raw material for aluminum oxide in the step of depositing aluminum oxide. Aluminum compounds, which are the raw material of aluminum oxide, are preferably organic aluminum compounds. As the organic aluminum compounds, trialkyl aluminum compounds, trialcoxy aluminum compounds, and dialkyl aluminum halide compounds such as dimethyl aluminum chloride can be used. Due to the increased durability and good handling of the resulting silicate fluorescent materials, the organic aluminum compounds are preferably trialkyl aluminum having three alkyl groups, in which trialkyl aluminum with each of the alkyl groups having one to three carbons are more preferable. Among trialkyl aluminum, trimethyl aluminum is further preferable in terms of handling of the silicate fluorescent materials to which trimethyl aluminum is applied.

When the organic aluminum compound is, for example, trialkyl aluminum, oxygen can be introduced to carry out oxidation treatment, such that aluminum oxide can be deposited on the core particles of the silicate fluorescent composition. By way of example, a chemical equation for producing aluminum oxide from trimethylaluminum with introducing oxygen is shown below.

2Al(CH₃)₃+12O₂→Al₂O₃+6CO₂+9H₂O

Through such oxidation, aluminum oxide is produced from trialkyl aluminum, and aluminum oxide is deposited on the surfaces of the core particles of the silicate fluorescent composition.

In the process of applying aluminum oxide, it is preferable to use a raw gas containing trimethyl aluminum. When aluminum oxide is deposited via a CVD technique using a fluidized bed to be described below, it is preferable to vaporize trimethyl aluminum employed for the raw material gas in the fluidized gas employed for the fluidized bed, and using a mixed gas of the raw material gas and the fluidized gas, the fluidized bed is formed. The amount of raw material gas contained in the mixed gas of raw material gas and fluidized gas is preferably in a range of 0.5 to 3.5 volume %, or may be in a range of 1.0 to 3.0 volume %.

In the step of depositing aluminum oxide, it is preferable to use a CVD technique using a fluidized bed to deposit aluminum oxide. The CVD technique using a fluidized bed allows aluminum oxide to be deposited to the entire surfaces of core particles of the silicate fluorescent composition, forming a film of aluminum oxide on the surfaces of core particles of the silicate fluorescent composition. When a film of aluminum oxide is formed on the entire surfaces of the core particles of the silicate fluorescent composition, the core particles can be protected from heat and moisture caused by excited light (moisture or hydroxyl groups (OH)) etc., highly durable silicate fluorescent materials can be obtained even when used in a light emitting device that drive at high temperatures and humidity. For example, a fluidized bed CVD device can be used as a device to form a fluidized bed.

In the process of adhering aluminum oxide, it is desirable that the fluidized gas that forms the fluidized layer is nitrogen gas. If the fluidized gas is a nitrogen gas, it is desirable that the nitrogen concentration of the fluidized gas is 100 volume %, and it can be 99 volume %, or 98 volume %.

In the process of applying aluminum oxide, for example, when using a fluidized layer CVD device, core particles of the silicate fluorescent composition are injected into the reaction tube where the fluidized layer is formed, for example, from the bottom of the reaction tube, to supply a mixture of raw gas and fluidized gas containing organic aluminum compounds. Oxygen is preferably supplied to the reaction tube to react with the raw material gas of vaporized organic aluminum compound. For example, when a mixed gas containing the raw material gas and the fluidized gas is supplied from the bottom of the reaction tube, oxygen may be supplied from the top of the reaction tube or may be supplied from the bottom of the reaction tube. It is preferable to supply oxygen from the top of the reaction tube because it is easy to react with the raw material gas in the mixed gas supplied from the bottom of the reaction tube. Oxygen is supplied such that the concentration of oxygen in the atmosphere is preferably in a range of 5 to 60 volume %, or may be in a range of 10 to 55 volume %, or may be in a range of 20 to 50 volume %. or less.

While depositing aluminum oxide on the surfaces of the core particles of the silicate fluorescent composition by using a CVD technique, heat treating is preferably performed at a temperature in a range of 210 to 490° C. in an oxygen-containing atmosphere. By heat treating at a temperature in a range of 210 to 490° C., oxygen defects present in the crystal structure of the core particles of the silicate fluorescent composition can be compensated with oxygen in the oxygen-containing atmosphere without damaging the crystal structure of the core particles of the silicate fluorescent composition while improving the reactivity of the raw material such as trialkyl aluminum, to form a film containing aluminum oxide on almost the entire surfaces of the core particles. Accordingly, the resulting silicate fluorescent material has good durability to maintain the luminous flux even in high temperatures and high humidity, without reducing luminance. Further, by heat treating in an oxygen-containing atmosphere, while depositing aluminum oxide on the surfaces of the core particles by using a CVD technique, the water or hydroxyl groups (OH) attached to the surfaces of the core particles can be removed, which is estimated to increase adhesion between core particles of the silicate fluorescent composition and aluminum oxide. The temperature of heat treatment in an oxygen-containing atmosphere can be in a range of 250 to 450° C., or can be in a range of 300 to 400° C.

The duration of heat treating in an oxygen-containing atmosphere at a temperature in a range of 210 to 490° C. while depositing aluminum oxide may be 1 hour or longer, may be in a range of 1 to 24 hours, or may be in a range of 2 to 20 hours.

### Depositing Aluminum Oxide Using CVD Technique

As shown in FIG. 2 and FIG. 3, when two separate steps: a step of depositing aluminum oxide (S102A) and a step of heat treating (S102B) are performed, the temperature of the atmosphere in which the step of depositing aluminum oxide is performed using a CVD technique may be less than 210° C. or may be less than 200° C. Even when the step of depositing aluminum oxide using a CVD technique and the step of heat treating are performed as separate steps, aluminum oxide can be deposited using the same or similar materials and steps as those used in the step of heat treating while depositing aluminum oxide. Even when the step of depositing aluminum oxide using a CVD technique and the step of heat treating in an oxygen-containing atmosphere are performed as separate steps, the atmosphere temperature in the step of depositing aluminum oxide using a CVD technique is preferably less than 500° C. and less than 490° C. to avoid damage to the core particles of the silicate fluorescent composition caused by heat treating.

### Heat Treating in Oxygen-Containing Atmosphere

When the step of depositing aluminum oxide using a CVD technique and the step of heat treating in an oxygen-containing atmosphere are performed as separate steps, the step of heat treating is performed at a temperature in a range of 210 to 490° C. in the oxygen-containing atmosphere before and/or after the step of depositing aluminum oxide using a CVD technique. In the heat treating, the fluidized layer CVD device for depositing aluminum oxide using CVD technique can be used. When using a fluidized layer CVD device, oxygen is preferably supplied in the reaction tube where core particles of the silicate fluorescent composition are present, before and/or after depositing aluminum oxide, so that the concentration of oxygen in the atmosphere in the reaction tube is in a range of 10 to 80 volume %. The oxygen is supplied such that the concentration of oxygen in the atmosphere is preferably in a range of 5 to 60 volume %, may be in a range of 10 to 55 volume %, or may be in a range of 20 to 50 volume %. Oxygen may be supplied from the top of the reactor tube or from the bottom of the reactor tube. The heat treating in the oxygen-containing atmosphere may be performed using a device other than a fluidized layer CVD device.

The heat treating in the oxygen-containing atmosphere can be performed at a temperature in a range of 210 to 490° C., preferably in a range of 220 to 480° C., more preferably in a range of 250 to 450° C., further preferably in a range of 280 to 420° C., and further more preferably in a range of 300 to 400° C. When the heat treating in the oxygen-containing atmosphere is carried out at a temperature in a range of 210 to 490° C., the hydroxyl groups (OH), or water, which was attached to the surfaces of the core particles of the silicate fluorescent composition, can be removed while oxygen defects present in the crystal structure of the core particles are compensated with oxygen in the oxygen-containing atmosphere, without damaging the structure of the score particles caused by the heat treating, and accordingly, silicate fluorescent material can be obtained with improved adhesion between the core particles and aluminum oxide.

In the oxygen-containing atmosphere, heat treatment time at the temperature in a range of 210 to 490° C. and below are preferred over 1 hour and under 24 hours in total for the temperature range of 210 to 490° C. and over 2 hours and 20 hours, and over 3 hours and 18 hours in more favorable conditions. When the heat treating in the oxygen-containing atmosphere at a temperature in a range of 210 to 490° C. is performed for a total time between 1 and 24 hours, oxygen defects present in the crystal structure of the core particles of the silicate fluorescent composition can be compensated with oxygen in the oxygen-containing atmosphere without damaging the crystal structure of the core particles while improving adhesion between the core particles and aluminum oxide. Accordingly, it is possible to obtain a silicate fluorescent material having high durability, in which a degradation of luminance in early stage of lighting can be reduced and good durability that can maintain the luminous flux even in high temperatures and high humid conditions.

Even when the step of depositing aluminum oxide on the surfaces of the silicate fluorescent material particles by using a CVD technique and the step of heat treating in the oxygen-containing atmosphere at a temperature in a range of 210 to 490° C. are performed separately, by performing the both steps, while compensating oxygen defects present in the crystal structure of core particles of the silicate fluorescent composition with oxygen in the oxygen-containing atmosphere, moisture or hydroxyl groups (OH) present on the surfaces of the core particles can also be removed. Accordingly, adhesion between the core particles and aluminum oxide can be increased and a film containing aluminum oxide can be disposed on the entire surfaces of the core particles.

The silicate fluorescent material thus obtained has good durability and can exhibit stable initial luminance, the core particles are protected from heat caused by the excitation light and moisture by the film containing aluminum oxide on the surfaces of the core particles, such that even when the light emitting device is operated under high temperature and high humidity, the luminous flux can be maintained.

### Silicate Fluorescent Material

The silicate fluorescent material according to the certain embodiments of the present disclosure include core particles of the silicate fluorescent composition and a film containing aluminum oxide on the surfaces of the core particles, the core particles may include a composition that includes: at least one element M selected from the group consisting of Ca, Sr, and Ba, and Mg, Eu, and Si, and optionally Mn, when the molar ratio of Si in the 1 mole of the composition is 2, the sum of the molar ratio of M and Eu is a product of 3 and the variant a, the sum of the molar ratio of Mg and Mn is a variant b, the molar ratio of Eu is a product of 3 and the variant a and the variant c, and the molar ratio of Mn is a product of the variant b and the variant d. In the composition, the variant a is in a range of 0.93 to 1.07, the variant b is in a range of 0.90 to 1.10, the variant c is in a range of 0.016 to 0.090, and the variant d is in a range of 0 to 0.22. The amount of aluminum in the film containing aluminum oxide is in a range of 0.86 mass % to 0.98 mass % with respect to the total mass amount of the silicate fluorescent material.

The silicate fluorescent material is preferably produced using the method of producing silicate fluorescent material described above. In the silicate fluorescent material, a film containing aluminum silicate is provided on the surfaces of core particles of the silicate fluorescent composition. The amount of aluminum in the film is in a range of 0.86 mass % to 0.98 mass % relative to a total mass amount of the silicate fluorescent material. Based on the content of the aluminum in the silicate fluorescent material, it is estimated that the film containing aluminum oxide is formed on the entire surfaces of the core particles. The silicate fluorescent material is protected from heat from excitation light and moisture present in the outside air by the film containing aluminum oxide formed throughout the surfaces of core particles and a reduction in the luminance can be reduced or prevented, such that even when used in a light emitting device configured to be operated at high temperatures and high humidity, the luminance can be maintained and good durability can be exhibited. The aluminum content preferably is in a range of 0.87 mass % to 0.98 mass %, more preferably in a range of 0.89 mass % to 0.97 mass %, and further preferably in a range of 0.90 mass % to 0.96 mass % relative to a total mass amount of the silicate fluorescent material.

It is preferable that the core particles of the silicate fluorescent composition contained in the silicate fluorescent material are preferably produced using the method described above. The core particles preferably includes a composition represented by the formula (M_{1-c}Eu_{c})₃ₐ(Mg_{1-d}Mn_{d})_{b}Si₂O₈ as shown above. The variable c is preferably in a range of 0.016 to 0.090 (0.016≤c≤0.090), may be in a range of 0.022 to 0.082 (0.022≤c≤0.082), may be in a range of 0.025 to 0.079 (0.025≤c≤0.079), or may be in a range of 0.031 to 0.072 (0.031≤c≤0.072). The variable d may be in a range of 0.009 to 0.11 (0.009≤d≤0.11).

The silicate fluorescent material has an average particle size (Fisher size) measured using a Fisher Sub-sieve Sizer method (also known as a “FSSS method”), in a range of 1 to 45 μm, may be in a range of 3 to 42 μm, may be in a range of 5 to 40 μm, or may be in a range of 10 to 35 μm. When the average particle size of the silicate fluorescent material measured using the FSSS method is in a range of 1 to 45 μm, good luminescence properties can be obtained and can be easily handled in the production of the luminescent device. The FSSS method uses an air permeability method [technique], deriving a specific surface area of a powder from a resistance to passing air to mainly determine the size of primary particles.

It is preferable that the silicate fluorescent material is configured to absorb light having a peak emission wavelength in a range of 250 nm to 460 nm which is in ultraviolet range to visible light range, and emit blue light having a peak emission wavelength in a range of 440 nm to 485 nm. The silicate fluorescent material may be configured to absorb light having a peak emission wavelength in a range of 250 nm to 460 nm and emit light having a peak emission wavelength in a arrange of 445 nm to 480 nm, or emit light having a peak emission wavelength in a range of 440 nm to 475 nm. The silicate fluorescent material efficiently absorbs light having a peak emission wavelength in a range of 250 nm to 460 nm, and produces light with a high luminance.

The silicate fluorescent material can be used, for example, in combination with an excitation light source such as an LED and LD, in a lighting device, a light emitting device for backlighting of an LCD display, etc. The silicate fluorescent materials each configured to emit green light, yellow light, red light, or deep red light can be appropriately selected and used in combination in a light emitting device configured to emit while light, that can be obtained by mixing light emitted from excitation light source and light emitted from the silicate fluorescent materials.

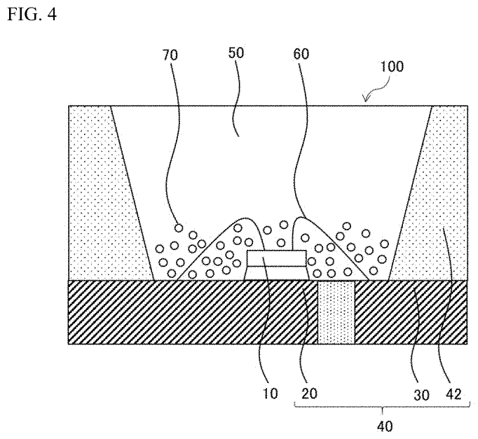

One example of the light emitting devices using one or more of the silicate fluorescent materials will be described below. FIG. 4 is a schematic cross-sectional view illustrating an example of a light emitting device using the silicate fluorescent material. The light emitting device includes the silicate fluorescent material described above and an excitation light source.

### Light Emitting Device

The light emitting device 100 according to the present embodiment includes a molded body 40 which defines a recess opening upward, a light emitting element 10 configured to serve as a light source, and a fluorescent member 50 covering the light emitting element 10. The molded body 40 is formed by integrally molding a first lead 20 and a second lead 30 with a resin composition 42 that contains a thermoplastic resin or a thermosetting resin. The recess that opens upward is defined by an upward-facing surface formed with the first lead 20 and the second lead 30 and inner lateral surfaces formed with the resin part 42. The light emitting element 10 is mounted on the upward-facing surface of the recess of the molded body 40. The light emitting element 10 has positive and negative electrodes that are respectively electrically connected with the first lead 20 and the second lead 30 through respective wires 60. The light emitting element 10 is covered by the fluorescent member 50. The fluorescent member 50 contains, a fluorescent material 70 containing the silicate fluorescent material to convert the wavelength of light emitted from the light emitting element 10 that is the excitation light source. The fluorescent member 50 is configured to serve not only as a wavelength converting member but also as a member for protecting the light emitting element 10 and the fluorescent material 70 containing the silicate fluorescent material from the external environment. The light emitting device 100 is configured to emit light when electric power is supplied from outside through the first lead 20 and the second lead 30.

### Light Emitting Element

A light emitting element such as an LED or an LD can be used for the excitation light source. The light emitting element preferably has a peak emission wavelength in a range of 250 to 460 nm. In order to excite the fluorescent material efficiently, the light emitting element preferably has a peak emission wavelength in a range of 300 to 450 nm, more preferably in a range of 350 to 440 nm. The use of such a light emitting element as the excitation light source allows to form a light emitting device that can emit a mixed color of light of a predetermined color temperature or predetermined color.

The light emitting element has an emission spectrum with a half value width of, for example 30 nm or less. For the first light emitting element, a semiconductor light emitting element is preferably used. With the use of a semiconductor light emitting element as a light source, a light emitting device having high efficiency with a high linearity of outputting with respect to inputting, and having high stability to mechanical impacts can be obtained. The semiconductor light emitting element may be, for example, a semiconductor light emitting element that uses a nitride-based semiconductor. In the present specification, the term “half value width” of a light emitting element and a fluorescent material refers to a width of an emission spectrum curve between points which are 50% of the maximum value of emission intensity in the emission spectrum.

### Fluorescent Member

The fluorescent member preferably contains the silicate fluorescent material, and a resin to protect the light emitting element and the fluorescent material from the external environment. The fluorescent member may contain a fluorescent material having a peak emission wavelength different from that of the silicate fluorescent material as needed. By including the silicate fluorescent material and a fluorescent material having a peak emission wavelength different from that of the silicate fluorescent material, it is possible to produce a mixed-color light with a predetermined color temperature and wide color reproducibility or/and high color rendering properties.

The amount of the silicate fluorescent material contained in the light emitting device can be appropriately determined according to a target color. For example, the content of the silicate fluorescent material in the fluorescent member can be in a range of 2 to 200 parts by mass, may be in a range of 10 to 100 parts by mass, or may be in a range of 10 to 50 parts by mass, with respect to 100 parts by mass of resin in the fluorescent member. When the content of the silicate fluorescent material in the fluorescent member is in a range of 2 to 200 parts by mass with respect to 100 parts by mass of resin in the fluorescent member, light emitted from the excitation light source can be efficiently converted by the fluorescent material.

Examples of resin contained in the fluorescent member include thermosetting resins such as silicone resin, epoxy resin, silicone resin, epoxy modified silicone resin, and modified silicone resin.

The fluorescent member may further contain a filler, a light diffusing material, or the like, in addition to the resin and the fluorescent material. For example, with a filler or light diffusing material contained in the fluorescent member, the directivity of light from the light excitation light source can be relaxed, allowing an expansion of the viewing angle. Examples of the filler and light diffusing material include silica, titanium oxide, zinc oxide, zirconium oxide, and alumina. For example, when the fluorescent member includes a filler or light diffusing material, the content of the filler or light diffusing material can be in a range of 1 to 20 parts by mass with respect to 100 parts by mass of the resin contained in the fluorescent member.

### EXAMPLES

Next, the present disclosure will be more specifically described with reference to examples, which however are not intended to limit the present disclosure.

### Example 1

### Step of Providing Raw Material Mixture and Obtaining Core Particles of Silicate Fluorescent Composition

The each of element sources SrCO₃, Eu₂O₃, MgO and SiO₂ were used as raw materials. Each of element sources were weighed to satisfy respective charge ratios, such that the molar ratio of the elements Sr, Eu, and Mg, with respect to the molar ratio of Si as 2, satisfy Sr:Mg:Eu:Si=2.85:1.00:0.15:2.00. Each element source was weighed to produce a composition of the above expression, in which the variable a is 1, the variable c is 0.05, the variable B is 1, and the variable d is 0. A flux of SrCl₂ was added, one part by mass to a total 100 parts by mass of each compound that does not contain a flux. The element sources were mixed in a ball mill using alumina balls as the medium to obtain a raw material mixture. The raw material mixture was placed in an alumina crucible and calcined in a reducing atmosphere at 1,400° C. for 4 hours. Because the particles of calcined product were aggregated together, alumina beads were used to disperse the calcined product in deionized water, then subsequently, classification was performed to remove coarse particles and fine particles, and the s core particles of the silicate fluorescent composition of about 18 μm in center particle size were obtained. The core particles of the silicate fluorescent composition included Sr as the element M, and Mg, Eu, and Si, and was estimated that in one mole of the composition, the molar ratio of Si was 2.00, the variable a was 1, the variable c was 0.05, the variable b was 1, and the variable d was 0, and had the composition represented by the formula described above.

### Step Including Depositing Aluminum Oxide Using CVD Technique, and Heat Treating

A 300 g of the silicate fluorescent material particles were placed in a reaction tube of a fluidized bed CVD reactor for particle coating. Nitrogen gas (N₂) was used as fluidizing gas, which was bubbled through trimethyl aluminum (TMA) used as a source material, and a mixed gas of a source gas and a fluidized gas was supplied from a lower portion of the reaction tube. Oxygen (O₂) was supplied from an upper part of the reactor tube at a flow rate to reach a concentration of 45 volume % oxygen in the atmosphere of the reaction tube. At a temperature of the atmosphere in the reaction tube 300° C., the heating processing was carried out in the oxygen-containing atmosphere for 6.5 hours while depositing aluminum oxide on the surfaces of the core particles of the silicate fluorescent composition using the CVD technique. Accordingly, a film containing aluminum oxide was deposited on the entire surfaces of the core particles of the silicate fluorescent composition, and thus the silicate fluorescent material according to Example 1 was obtained.

### Example 2

The silicate fluorescent material according to Example 2 was obtained in a similar manner as in Example 1, except that the temperature of the atmosphere in the reaction tube was 400° C. While depositing aluminum oxide on the surfaces of the core particles of the silicate fluorescent composition by using a CVD technique, a heat treating was performed in the oxygen-containing atmosphere and the silicate fluorescent material in which the film containing aluminum oxide was formed on the entire surfaces of the core particles was obtained.

### Comparative Example 1

Core particles of the silicate fluorescent composition were produced in a similar manner as in Example 1 except that depositing aluminum oxide using a CVD technique and the heat treating were not performed, and the silicate fluorescent material according to Comparative Example 1 was obtained.

### Comparative Examples 2 to 4

Except that the temperature in the reaction tube was set 100° C. in Comparative Example 2, 200° C. in Comparative Example 3, and 500° C. in Comparison Example 4, as in Example 1, while depositing aluminum oxide on the surfaces of the core particles of the silicate fluorescent composition by using a CVD technique, a heat treating was performed in the oxygen-containing atmosphere and the silicate fluorescent materials according to Comparative Examples 2 to 4 were respectively obtained.

### Comparative Example 5

Aluminum chloride ion water was produced by stirring 600 mL of deionized water and adding 19 g of aluminum chloride hexahydrate (AlCl₃, 6H₂O). In aluminum chloride ion water, 200 g of the core particles of the silicate fluorescent composition produced in a similar manner as in Example 1 were added and stirred for 10 minutes to deposit aluminum hydroxide on the surfaces of core particles. A slurry of aluminum hydroxide deposited on the surfaces of the score particles was taken out and dried at 105° C. for 15 hours. The dried particles were placed in an alumina crucible and heat treating was performed in the atmosphere at 400° C. for 6.5 hours and a silicate fluorescent material according to Comparative Example 5, having aluminum hydroxide deposited on the surfaces of the core particles of the silicate fluorescent composition was obtained.

### Comparative Example 6

Core particles of the silicate fluorescent composition produced in a similar manner way as in Example 1 were placed in an alumina crucible and heat treating was performed in the atmosphere at 300° C. for 6.5 hours and a silicate fluorescent material according to Comparative Example 6 was obtained.

### Comparative Example 7

Silicate fluorescent material according to Comparative Example 7 was obtained in a similar manner as in Comparative Example 6 except that the heat treating was performed at a temperature of 400° C.

### Comparative Example 8

The core particles of the silicate fluorescent composition produced in a similar manner as in Example 1 were fluidized in the reaction chamber, and using trimethyl aluminum (TMA) and water vapor, an ALD cycle (Step A and Step B described below) was repeated for 100 cycles at 180° C., and a silicate fluorescent material according to Comparative Example 8, having aluminum oxide deposited on the surfaces of the silicate fluorescent material core particle was obtained.

Step A: Water vapor (H₂O) was introduced into the chamber and the excess water vapor was sucked in vacuum or purged with nitrogen (N₂) gas.

Step B: Trimethyl aluminum (TMA) was introduced into the chamber and the excess TMA was sucked in vacuum or purged with nitrogen (N₂) gas.

### Evaluation and Luminescence Characteristics of Silicate Fluorescent Material

For each silicate fluorescent material illustrated in the examples and comparative examples, an excitation light of wavelength 420 nm was irradiated to measure the luminance at room temperature, using a fluorescence spectrophotometer (Hitachi High-Tech Science, Inc., F-4500).

The luminance of the silicate fluorescent material according to Comparative Example 1 was set to 100%, the luminance of each silicate fluorescent material of the examples and comparative examples was determined as relative luminance.

### Analyzing Aluminum Element

For each silicate fluorescent material illustrated in the examples and comparative examples, the content (mass %) of Al element with respect to the total amount of the silicate fluorescent material was measured using an inductively coupled Plasma-Atomic Emission Spectrometry (ICP-AES) (Perkin Elmer, Optima8300).

### Light Emitting Device Using Silicate Fluorescent Material

Light emitting devices each including a corresponding one of the silicate fluorescent materials according to Examples and Comparative Examples, and a nitride-based semiconductor light emitting element having a peak emission wavelength of 420 nm as the light emitting element were produced. Each of the silicate fluorescent materials was dispersed in a silicone resin to form a fluorescent material composition, which was then applied to cover the nitride-based semiconductor light emitting element, and thus each of the fluorescent members was formed. In each fluorescent member, the content of the silicate fluorescent material was adjusted such that the color of a mixed light of the light emitted from the nitride-based semiconductor light emitting element and the light from the fluorescent member satisfies the CIE1931 chromaticity coordinates (x, y) of x in a range of 0.138 to 0.139 (x=0.138 to 0.139) and y in a range of 0.065 to 0.068 (y=0.065 to 0.139), specified by the Comission International de l'eclairage (CIE), to produce each of the light emitting devices. More specifically, each of the light emitting devices of the examples and comparative examples includes the fluorescent member in which a content of a corresponding one of the silicate fluorescent material satisfied the content shown in Table 1, with respect to the 100 parts per mass of the silicone resin.

### Evaluation of Light Emitting Device

### Relative Luminous Flux of LED

For each light emitting device of the examples and comparative examples, the luminous flux was measured using an optical measuring system that employs a combination of a spectroscopic spectrometer (Hamamatsu Photonics, PMA-11) and an integral sphere. The luminous flux of the light emitting device using the silicate fluorescent materials according to Comparative Example 1 was set to 100%, the luminous flux of each of the light emitting devices using a corresponding one of the silicate fluorescent materials according to examples and comparative examples was expressed as a relative luminous flux.

### Durability Test and Luminous Flux Maintenance Ratio of LED

The durability test was conducted by continuously operating each light emitting device according to the examples and the comparative examples at a temperature of 85° C. a relative humidity of 85% for 500 hours in an environment test device with a driving current of 150 mA. The LED luminous flux maintenance ratio (%) is expressed as 100% of the luminous flux at 0 hour and as the luminous flux maintenance rate after the durability test.

### SEM Image—Secondary Electron Image

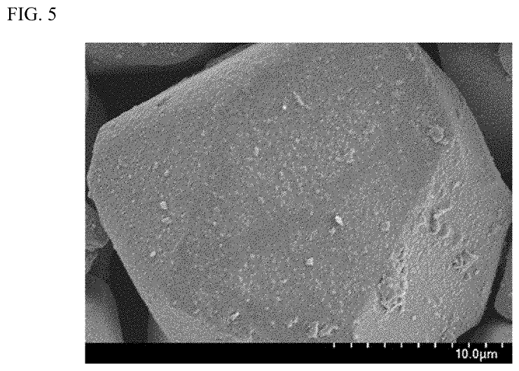

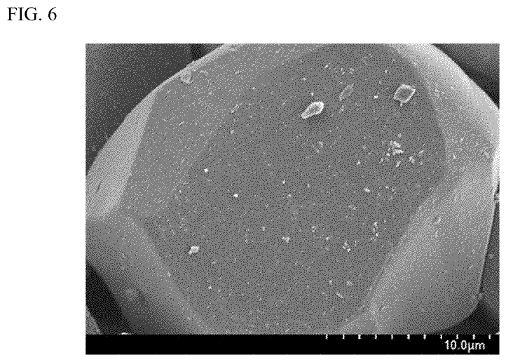

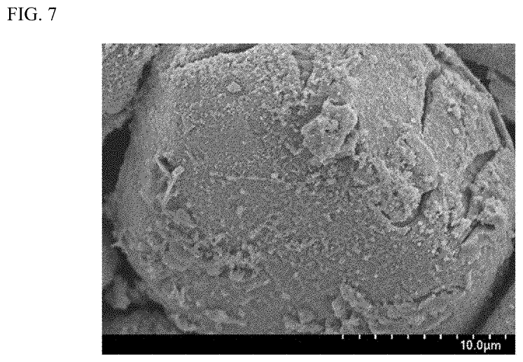

Using a scanning electron microscope (SEM: manufactured by Hitachi High Technologies, Ltd., SU3500), SEM images of silicate fluorescent materials according to Example 2, Comparative Example 1, and Comparative Example 5 were obtained. FIG. 5 is an SEM image of the silicate fluorescent material according to Example 2. FIG. 6 is an SEM image of the silicate fluorescent material according to Comparative Example 1. FIG. 7 is an SEM image of the silicate fluorescent material according to Comparative Example 5.

TABLE 1

| | | | silicate fluorescent | | Light emitting device | | |
|---|---|---|---|---|---|---|---|
| | | | material | | | | Luminous Flux |
| | | | | Relative | | | Maintenance |
| | | | | Luminance | Content of | | Ratio (%) |
| | Treatment Method | | | (%) | Fluorescent | Relative | (85° C., 85%, |
| | Treatment + | Temperature | Al | 420 nm | material | Luminous | 150 mA) |
| | Deposit | (° C.) | (mass %) | excitation | (pts. mass) | Flux (%) | 500 hours |
| Comparative | core particles of silicate | | 32 mass | 100.0 | 50 | 100.0 | 64.3 |
| Example 1 | fluorescent composition | | ppm | | | | |
| Comparative | | 100 | 0.84 | 90.5 | 62 | 95.6 | 70.0 |
| Example 2 | | | | | | | |
| Comparative | | 200 | 0.85 | 99.8 | 60 | 97.9 | 71.6 |
| Example 3 | | | | | | | |
| Example 1 | | 300 | 0.93 | 99.4 | 60 | 96.4 | 88.1 |
| Example 2 | | 400 | 0.95 | 94.3 | 60 | 95.1 | 96.9 |
| Comparative | | 500 | 0.99 | 86.6 | 65 | 91.1 | 98.5 |
| Example 4 | | | | | | | |
| Comparative | CVD-Al₂O₃ | 400 | 0.87 | 83.2 | 55 | 88.9 | 87.6 |
| Example 5 | | | | | | | |
| Comparative | Al(OH)₃ | 300 | — | 99.5 | 55 | 97.5 | 75.2 |
| Example 6 | Atmosphere | | | | | | |
| Comparative | Atmosphere | 400 | — | 90.0 | 60 | 92.3 | 92.4 |
| Example 7 | | | | | | | |
| Comparative | ALD-Al₂O₃ | 180 | 390 mass | 99.8 | 50 | 99.5 | 78.5 |
| Example 8 | | | ppm | | | | |

The silicate fluorescent materials according to Examples 1 and 2 did not exhibit a significant reduction in their initial relative luminance compared with the silicate fluorescent materials according to Comparative Example 1, to which aluminum oxide was not deposited on the surfaces of the core particles of the silicate fluorescent composition, and exhibited maintaining of good relative luminance of the silicate fluorescent materials. The silicate fluorescent materials according to Examples 1 and 2 were heat treated at temperatures in a range of 210° C. to 490° C. in the oxygen-containing atmosphere while depositing aluminum oxide on the surfaces of the core particles of the silicate fluorescent composition using a CVD technique. Thus, it is estimated that without damaging the crystal structure of the core particles of the silicate fluorescent composition, oxygen defects present in the crystal structure of silicate fluorescent material core particles were compensated with oxygen in the atmosphere, and a film containing aluminum oxide was formed on the surfaces of the core particles of the silicate fluorescent composition, while removing water or hydroxyl groups (OH) that were attached to the surfaces of the core particles of the silicate fluorescent composition.

The light emitting devices using the silicate fluorescent materials according to Examples 1 and 2 highly maintained the relative luminous flux that were exhibited before the durability test. In addition, the light emitting device using the silicate fluorescent materials according to Examples 1 and 2 had a high luminous flux maintenance rate and good durability after a durability test of 500 hours of continuous illumination under high temperature and high humidity, at the temperatures of 85° C. and the relative humidity of 85%.

In the silicate fluorescent materials according to Examples 1 and 2, the content of aluminum were 0.93 mass % and 0.95 mass % respectively to the total amount of corresponding fluorescent material, which were sufficient amount of aluminum to form a film containing aluminum oxide on the entire surfaces of the core particles of the silicate fluorescent composition, and thus it was estimated that a film of aluminum oxide is deposited using a CVD technique on the entire surfaces of the core particles of the silicate fluorescent composition. Thus, the silicate fluorescent materials according to Examples 1 and 2 had a high flux maintenance rate even after the durability test.

Aluminum oxide was not deposited on the silicate fluorescent materials according to Comparative Example 1, and the heat treating was not performed. Thus, although the initial relative luminance was high, and the relative luminous flux of the light emitting device using the silicate fluorescent material according to Comparative Example 1 prior to the heat treating was high, the luminous flux maintenance rate after the durability test was low. The results suggest that the silicate fluorescent material according to Comparative Example 1 deteriorated due to the heat of the excitation light and moisture or the hydroxyl groups (OH).

In the silicate fluorescent materials according to Comparative Examples 2 and 3, aluminum oxide was deposited on the surfaces of the silicate fluorescent material particles using a CVD technique and heat treating was performed in the oxygen-containing atmosphere. However, because the heat treating was performed at a low temperature of 200° C. or less, it was estimated that oxygen defects in the crystal structure of the core particles of the silicate fluorescent composition were difficult to be compensated with oxygen, and the moisture or hydroxyl groups (OH) attached on the surfaces of the core particles of the silicate fluorescent composition were not sufficiently removed, resulting in low adhesion between the core particles of the silicate fluorescent composition and aluminum oxide. The light emitting devices using the silicate fluorescent materials according to Comparative Examples 2 and 3 exhibited a high relative luminous flux before the durability test, but the luminous flux maintenance rate after the durability test was lower than those according to Examples 1 and 2, which indicated that the durability was not improved.

In the silicate fluorescent material according to Comparative Example 4, aluminum oxide was deposited on the surfaces of the core particles of the silicate fluorescent composition using a CDV technique, and heat treating was performed in the oxygen-containing atmosphere. However, because the temperature of the heat treating was performed at a high temperature of 500° C. or greater, it was estimated that the crystal structure of the core particles of the silicate fluorescent composition was damaged by heat, and the relative luminance was reduced. In addition, the light emitting device using the silicate fluorescent material according to Comparative Example 4 exhibited a lower relative luminance flux before the durability test.

In the silicate fluorescent material according to Comparative Example 5, aluminum hydroxide was deposited on the surfaces of the core particles of the silicate fluorescent composition and heat treating was performed in the oxygen-containing atmosphere. However, it was estimated that the core particles of the silicate fluorescent composition were damaged by moisture or hydroxyl groups (OH) when depositing aluminum hydroxide, resulting in a lower relative luminance, and a lower relative luminance flux of the light emitting device using the silicate fluorescent material according to Comparative Example 5.

In the silicate fluorescent materials according to Comparative Examples 6 and 7, the core particles of the silicate fluorescent composition were heat-treated in the oxygen-containing atmosphere, a reduction in the oxygen defects in core particles of the silicate fluorescent composition and a high relative luminance were exhibited, and the light emitting device using the silicate fluorescent materials according to Comparative Examples 6 and 7 exhibited high relative luminous flux prior to the durability test, but the relative luminous flux after the durability test was low, indicating lack of improvement in the durability.

In the silicate fluorescent material according to Comparative Example 8, aluminum oxide was deposited on the surfaces of the core particles of the silicate fluorescent composition using an ALD technique, resulting in a high relative luminance and a high relative luminous flux prior to the durability test of the light emitting device using the silicate fluorescent material according to Comparative Example 8. However, the content of Al in the silicate fluorescent material was a low 390 mass ppm (0.039 mass %) due to the deposition of aluminum oxide by using an ALD technique, lacking a sufficient amount of aluminum oxide deposited on the core particles of the silicate fluorescent composition for protecting the particles from the heat from the excitation light, moisture, etc., resulting in a low luminous flux maintenance rate after the durability test.

From comparing FIG. 5 and FIG. 6, it was confirmed that the silicate fluorescent material according to Example 2 shown in FIG. 5 had minute recesses and protrusions over the entire surface of the silicate fluorescent material than the silicate fluorescent material according to Comparative Example 1 shown in FIG. 6. From the SEM image of the silicate fluorescent material according to Example 2 shown in FIG. 5, it was confirmed that aluminum oxide was deposited on the entire surface of the silicate fluorescent material according to Example 2. From comparing FIG. 5 and FIG. 7, compared to the surface of the silicate fluorescent material according to Example 2, cracks etc. were present on the film of aluminum oxide on the surface of the silicate fluorescent material according to Example 5, confirming that the aluminum oxide film was not uniformly deposited.

A silicate fluorescent material according to one aspect of the present disclosure can be suitably employed for a light source for lighting, an LED display, backlight source for a liquid crystal device, signals, a lighted switch, a light source for projector, various sensors, various indicators, etc.

It is to be understood that although the present invention has been described with regard to preferred embodiments thereof, various other embodiments and variants may occur to those skilled in the art, which are within the scope and spirit of the invention, and such other embodiments and variants are intended to be covered by the following claims.

What is claimed is:

1. A method of producing a silicate fluorescent material, the method comprising:
providing a raw material mixture that contains an M source containing M that is at least one element selected from the group consisting of Ca, Sr, and Ba, an Mg source, an Eu source, and an Si source, and optionally an Mn source, and obtaining core particles comprising a silicate fluorescent composition having a formula:
(M_{1-c}Eu_{c})₃ₐ(Mg_{1-d}Mn_{d})_{b}Si₂O₈,
wherein M is the at least one element selected from the group consisting of Ca, Sr, and Ba, and a, b, c, and d are numbers respectively satisfying 0.93≤a≤1.07, 0.90≤b≤1.10, 0.016≤c≤0.090, and 0≤d≤0.22;
using a chemical vapor deposition method, depositing aluminum oxide on surfaces of the core particles; and
heat treating at a temperature in a range of 210° C. to 490° C. in an oxygen-containing atmosphere.

2. A method of producing a silicate fluorescent material, the method comprising:
providing a raw material mixture that contains an M source containing M that is at least one element selected from the group consisting of Ca, Sr, and Ba, an Mg source, an Eu source, and an Si source, and optionally an Mn source, and obtaining core particles comprising a silicate fluorescent composition having a formula:
(M_{1-c}Eu_{c})₃ₐ(Mg_{1-d}Mn_{d})_{b}Si₂O₈,
wherein M is the at least one element selected from the group consisting of Ca, Sr, and Ba, and a, b, c, and dare numbers respectively satisfying 0.93≤a≤1.07, 0.90≤b≤1.10, 0.016≤c≤0.090, and 0≤d≤0.22;
heat treating at a temperature in a range of 210° C. to 490° C. in an oxygen-containing atmosphere; and
using a chemical vapor deposition method, depositing aluminum oxide on surfaces of the core particles.

3. The method of producing a silicate fluorescent material according to claim 1, wherein in depositing aluminum oxide, a raw material gas containing trimethyl aluminum is used.

4. The method of producing a silicate fluorescent material according to claim 1, wherein in depositing aluminum oxide, a raw material gas containing trimethyl aluminum is used.

5. The method of producing a silicate fluorescent material according to claim 1, wherein in depositing aluminum oxide, aluminum oxide is deposited using fluidized bed chemical vapor deposition.

6. The method of producing a silicate fluorescent material according to claim 2, wherein in depositing aluminum oxide, aluminum oxide is deposited using fluidized bed chemical vapor deposition.

7. The method of producing a silicate fluorescent material according to claim 5, wherein in depositing aluminum oxide, a fluidizing gas fluidizing the fluidizing bed is a nitrogen gas.

8. The method of producing a silicate fluorescent material according to claim 6, wherein in depositing aluminum oxide, a fluidizing gas fluidizing the fluidizing bed is a nitrogen gas.

9. The method of producing a silicate fluorescent material according to claim 1, wherein a content of oxygen in the oxygen-containing atmosphere is in a range of 5 volume percent to 60 volume percent.

10. The method of producing a silicate fluorescent material according to claim 2, wherein a content of oxygen in the oxygen-containing atmosphere is in a range of 5 volume percent to 60 volume percent.

11. The method of producing a silicate fluorescent material according to claim 1, wherein the heat treating is carried out at a temperature in a range of 250° C. to 450° C.

12. The method of producing a silicate fluorescent material according to claim 2, wherein the heat treating is carried out at a temperature in a range of 250° C. to 450° C.

13. The method of producing a silicate fluorescent material according to claim 1, wherein a film containing aluminum oxide is deposited on an entire surface of each of the core particles.

14. The method of producing a silicate fluorescent material according to claim 2, wherein a film containing aluminum oxide is deposited on an entire surface of each of the core particles.

15. A silicate fluorescent material comprising:
at least one core particle comprising a silicate fluorescent composition; and
a film containing aluminum oxide on a surface of the at least one core particle;
the silicate fluorescent composition including M that is at least one element selected from the group consisting of Ca, Sr, and Ba, and Eu, and Si, and optionally Mn;
wherein in the silicate fluorescent composition, when a molar ratio of Si is 2, a total molar ratio of M and Mn is a product of 3 and a variable a, a molar ratio of Eu is a product of 3, the variable a and a variable c, and a molar ratio of Mn is a product of a variable b and a variable d;
wherein in the silicate fluorescent composition, the variable a is in a range of 0.93 to 1.07, the variable b is in a range of 0.90 to 1.10, the variable c is in a range of 0.016 to 0.090, and the variable d is in a range of 0 to 0.22, and
an amount of aluminum in the film containing aluminum oxide is in a range of 0.86 mass % to 0.98 mass % relative to a total mass amount of the silicate fluorescent material.

16. The silicate fluorescent material according to claim 15, wherein the at least one core particle includes a composition represented by a formula:
(M_{1-c}Eu_{c})₃ₐ(Mg_{1-d}Mn_{d})_{b}Si₂O₈,
wherein M is at least one element selected from the group consisting of Ca, Sr, and Ba, and a, b, c, and d are numbers respectively satisfying 0.93≤a≤1.07, 0.90≤b≤1.10, 0.016≤c≤0.090, and 0≤d≤0.22.

17. The silicate fluorescent material according to claim 15, wherein the amount of aluminum in the film containing aluminum oxide is in a range of 0.90 mass % to 0.96 mass % relative to the total mass amount of the silicate fluorescent material.

18. A light emitting device comprising the silicate fluorescent material according to claim 15, and an excitation light source.

19. The light emitting device according to claim 18, wherein the excitation light source is a light emitting element having a peak emission wavelength in a range of 250 nm to 460 nm.
